(19) United States
(12) Patent Application Publication
(10) Pub. No.: US 2026/0271729 A1
(43) Pub. Date: Sep. 10, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventor: Yung-Ta LI, Taichung City (TW)

(73) Assignee: SILICONWARE PRECISION INDUSTRIES CO., LTD., Taichung City (TW)

(21) Appl. No.: 19/213,647

(22) Filed: May 20, 2025

(30) Foreign Application Priority Data
Mar. 6, 2025 (TW) 114108344

(51) Int. Cl. H01L 23/00; H01L 23/31; H01L 23/48; H01L 23/498; H01L 25/00

(52) U.S. Cl. CPC H10W 42/121; H10W 20/20; H10W 70/635; H10W 74/111; H10W 90/00

(57) ABSTRACT

An electronic package and a manufacturing method thereof are provided, in which a protective layer is formed on an inactive surface of an electronic component embedded in an encapsulation layer, and the protective layer is bonded to an insulating protective layer on the encapsulation layer, thereby improving the bonding between the electronic component and the insulating protective layer. Therefore, the delamination problem can be effectively avoided to ensure normal electrical conduction between conductive components on the insulating protective layer and conductive vias of the intermediate component embedded in the encapsulation layer.

### BACKGROUND

### 1. Technical Field

The present disclosure relates to a semiconductor packaging technology, and more particularly, to an electronic package that can improve reliability and a manufacturing method thereof.

### 2. Description of Related Art

In order to ensure the continued miniaturization and multi-functionality of electronic products and communication equipment, semiconductor packaging needs to be miniaturized to facilitate multi-pin connections, high-speed operation and high functionality. For example, in advanced process packaging, commonly used package types include fan-out wiring combined with the process of embedded components.

FIG. 1A is a schematic cross-sectional view of a conventional semiconductor package 1a. As shown in FIG. 1A, the conventional semiconductor package 1a includes: an encapsulation layer 15, a bridge chip 11 embedded in the encapsulation layer 15, an intermediate chip 12 embedded in the encapsulation layer 15, a plurality of conductive pillars 13 embedded in the encapsulation layer 15, a plurality of functional chips 16 disposed on one surface 15b of the encapsulation layer 15, and a plurality of solder balls 19 disposed on the other surface 15a of the encapsulation layer 15, wherein any two functional chips 16 are electrically bridged to each other via electrode pads 110 on an active surface 11a of the bridge chip 11, and any two functional chips 16 are electrically bridged to each other by conductive vias 120 of the intermediate chip 12.

However, in the method of manufacturing the conventional semiconductor package 1a, before the solder balls 19 are placed, the surface 15a of the encapsulation layer 15 needs to be leveled. At this time, the problem of uneven grinding surface (for example, the surface of the intermediate chip 12, the end surfaces of the conductive vias 120, the surface 15a of the encapsulation layer 15, the end surfaces of the conductive pillars 13, and the surface of the bridge chip 11 are not flush with each other) will arise due to the large differences in the materials to be removed (for example, semiconductor materials [the bridge chip 11 and the intermediate chip 12], insulating materials [the encapsulation layer 15] and copper materials [the conductive pillars 13 and the conductive vias 120] are not easy to grind), thereby resulting in an uneven grinding surface. Therefore, it is not conducive to the subsequent alignment and bonding of the solder balls 19, thereby resulting in poor reliability and yield of the semiconductor package 1a.

Moreover, there is no circuit structure on a back surface 11b of the bridge chip 11, and thus a dummy area is formed. The silicon material of the back surface 11b of the bridge chip 11 is different from the material of an insulating protective layer 14 used for positioning the solder balls 19, thereby resulting in poor bonding between the bridge chip 11 and the insulating protective layer 14. Therefore, delamination is prone to occur between the bridge chip 11 and the insulating protective layer 14, causing the solder balls 19 to be easily displaced or dropped, and resulting in poor reliability and yield of the semiconductor package 1a.

Therefore, in order to solve the problem of the solder balls 19 being displaced or dropped, the industry has added a circuit structure 112 on the back surface 11b of the bridge chip 11, as shown in FIG. 1B. In this way, the solder balls 19 are bonded to the circuit structure 112 by utilizing the easy bonding property of the metal material.

However, the circuit structure 112 is made of copper, which causes the back surface 11b of the bridge chip 11 to lose its passivation effect, thereby causing the problem of copper migration. Therefore, electrical short circuits are prone to occur between the electrode pads 110 on the active surface 11a of the bridge chip 11, causing electrical malfunction of the bridge chip 11, thereby resulting in poor reliability and yield of the semiconductor package 1.

Furthermore, the semiconductor package 1b shown in FIG. 1B still has the problem that the uneven grinding surface is not conducive to the alignment and bonding of the solder balls 19.

Therefore, how to overcome the above-mentioned drawbacks of the prior art has become an urgent issue to be solved.

### SUMMARY

In view of the various deficiencies of the prior art, the present disclosure provides an electronic package, which comprises: an encapsulation layer having a first surface and a second surface opposite to the first surface; an electronic component embedded in the encapsulation layer to serve as a bridge die and having an active surface and an inactive surface opposite to the active surface, wherein the active surface of the electronic component faces the second surface of the encapsulation layer; an intermediate component embedded in the encapsulation layer to serve as a bridge die and having a plurality of conductive vias; and a protective layer embedded in the first surface of the encapsulation layer and bonded to the inactive surface of the electronic component, wherein the protective layer is free from being formed on the intermediate component.

The present disclosure also provides a method of manufacturing an electronic package, and the method comprises: providing an electronic module, the electronic module comprising: an encapsulation layer having a first surface and a second surface opposite to the first surface, an electronic component embedded in the encapsulation layer to serve as a bridge die, and an intermediate component embedded in the encapsulation layer to serve as a bridge die, wherein the electronic component has an active surface and an inactive surface opposite to the active surface, and the active surface of the electronic component faces the second surface of the encapsulation layer, wherein the intermediate component has a plurality of conductive vias, and a protective layer embedded in the first surface of the encapsulation layer is disposed on the inactive surface of the electronic component and the intermediate component; and performing a leveling process on the first surface of the encapsulation layer to remove the protective layer on the intermediate component, wherein the protective layer on the electronic component is retained.

In the aforementioned electronic package and method, the present disclosure further comprises: forming an insulating protective layer having a plurality of openings on the protective layer on the electronic component and the first surface of the encapsulation layer; and forming a plurality of conductive blind vias in the plurality of openings to connect to a plurality of conductive components.

In the aforementioned electronic package and method, the present disclosure further comprises: forming an insulating protective layer having a plurality of openings on the intermediate component and the first surface of the encapsulation layer, wherein the plurality of openings correspond to the plurality of conductive vias; and forming a plurality of conductive blind vias in the plurality of openings, wherein the plurality of conductive blind vias are electrically connected to the plurality of conductive vias and connected to a plurality of conductive components.

In the aforementioned electronic package and method, the present disclosure further comprises: forming a routing structure on the protective layer on the electronic component and the first surface of the encapsulation layer.

In the aforementioned electronic package and method, the present disclosure further comprises: forming a routing structure on the intermediate component and the first surface of the encapsulation layer, wherein the routing structure is electrically connected to the plurality of conductive vias.

In the aforementioned electronic package and method, a width of each of the plurality of conductive vias is greater than 11 microns.

In the aforementioned electronic package and method, a width of each of the plurality of conductive vias is less than 11 microns.

In the aforementioned electronic package and method, a circuit structure is disposed on the second surface of the encapsulation layer and the active surface of the electronic component and is electrically connected to the electronic component. For example, a plurality of functional components are disposed on the circuit structure, and the electronic component and/or the intermediate component electrically bridge the plurality of functional components via the circuit structure.

In the aforementioned electronic package and method, the present disclosure further comprises: forming a passivation structure covering ends of the plurality of conductive vias on the intermediate component, wherein end surfaces of the plurality of conductive vias are exposed from the passivation structure.

As can be seen from the above, in the electronic package and the manufacturing method thereof according to the present disclosure, a protective layer embedded in the first surface of the encapsulation layer is disposed on both the inactive surface of the electronic component and the intermediate component. Therefore, the differences in the materials to be removed are smaller when the leveling process is performed on the first surface of the encapsulation layer. Accordingly, compared with the prior art, the present disclosure can avoid the problem of uneven grinding surface to form a flat grinding surface. This is beneficial to the subsequent alignment and bonding of the conductive components, thereby improving the reliability and yield of the electronic package.

Moreover, there is no circuit structure on the inactive surface of the electronic component, so that the conventional copper migration problem does not occur. Therefore, compared with the prior art, the present disclosure can effectively avoid the problem of electrical short circuit to ensure that the electrical function of the electronic component is normal, thereby improving the reliability and yield of the electronic package.

Furthermore, although there is no circuit structure on the inactive surface of the electronic component, the protective layer can enhance the bonding between the electronic component and the insulating protective layer. Therefore, compared with the prior art, the present disclosure can effectively avoid the delamination problem to ensure normal electrical conduction between the conductive components and the conductive vias, thereby improving the reliability and yield of the electronic package.

### BRIEF DESCRIPTION OF THE DRAWINGS

FIG. 1A is a schematic cross-sectional view of a conventional semiconductor package.

FIG. 1B is a schematic cross-sectional view of another conventional semiconductor package.

FIG. 2A to FIG. 2C are schematic cross-sectional views illustrating a method of manufacturing an electronic package according to a first embodiment of the present disclosure.

FIG. 3A to FIG. 3F are schematic cross-sectional views illustrating a method of manufacturing an electronic package according to a second embodiment of the present disclosure.

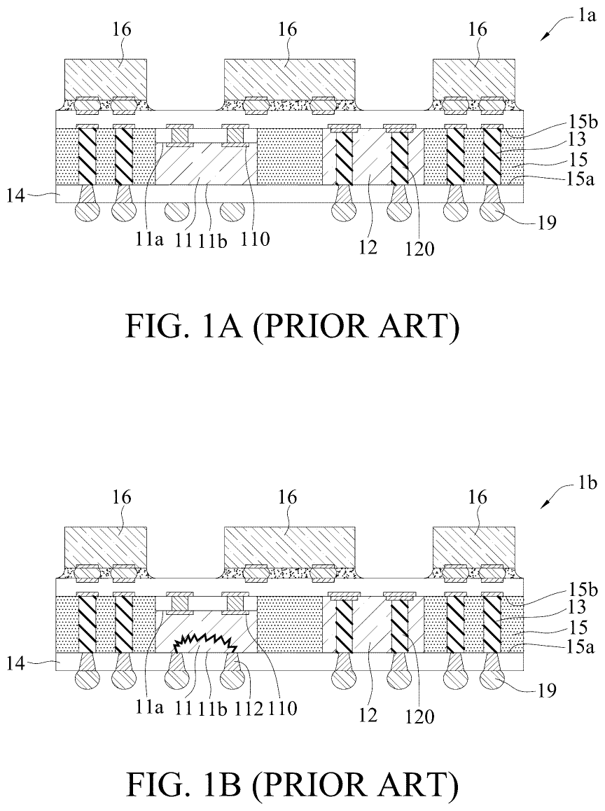

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “on,” “first,” “second,” “a,” “one,” and the like are merely for clear explanation rather than limiting the practicable scope of the present disclosure, and thus, alterations or adjustments of the relative relationships thereof without essentially altering the technical contents should still be considered in the practicable scope of the present disclosure.

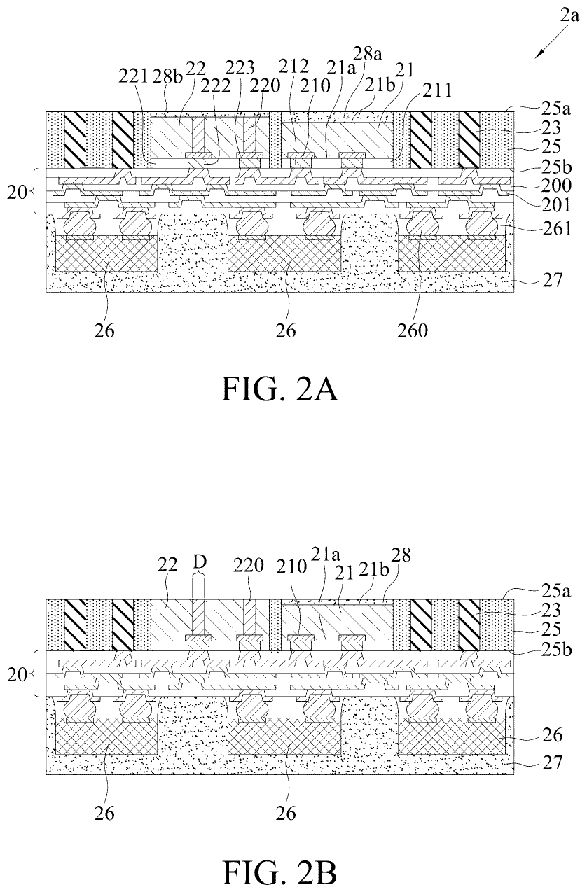

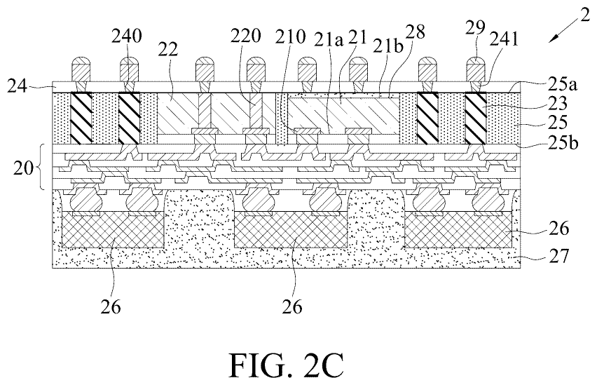

FIG. 2A to FIG. 2C are schematic cross-sectional views illustrating a method of manufacturing an electronic package 2 according to a first embodiment of the present disclosure.

As shown in FIG. 2A, an electronic module 2a is provided and comprises: an encapsulation layer 25, at least one electronic component 21, at least one intermediate component 22, at least one conductive pillar 23, a circuit structure 20, and at least one functional component 26.

The encapsulation layer 25 has a first surface 25a and a second surface 25b opposite to the first surface 25a.

In one embodiment, the encapsulation layer 25 is made of polyimide (PI), dry film, epoxy molding colloid, epoxy molding compound, or other insulating materials. For example, the encapsulation layer 25 may be formed by liquid compound, injection, lamination, compression molding, or other methods.

The electronic component 21 is embedded in the encapsulation layer 25, wherein the electronic component 21 is an active component, a passive component, or a combination of the active component and the passive component, wherein the active component is, for example, a semiconductor chip, and the passive component is, for example, a resistor, a capacitor, or an inductor.

In one embodiment, the electronic component 21 is a semiconductor chip and has an active surface 21a and an inactive surface 21b opposite to the active surface 21a. The active surface 21a of the electronic component 21 faces the second surface 25b of the encapsulation layer 25 and has a plurality of electrode pads 210 bonded and electrically connected to a plurality of conductors 212. The conductors 212 are encapsulated by a protective film 211 made of such as a passivation material. For example, the conductors 212 are conductive lines, spherical conductive elements such as solder balls, pillar-shaped conductive elements such as copper pillars or solder bumps, or stud-shaped conductive elements made by a wire bonding machine, but the present disclosure is not limited to as such.

Moreover, a protective layer 28a embedded in the first surface 25a of the encapsulation layer 25 is disposed on the inactive surface 21b of the electronic component 21. For example, the protective layer 28a is in the form of a die attach film (DAF) and is exposed from the first surface 25a of the encapsulation layer 25.

The intermediate component 22 is made of a semiconductor material, such as a silicon-based material. The intermediate component 22 has at least one conductive via 220, such as a conductive through-silicon via (TSV).

In one embodiment, each of a plurality of the conductive vias 220 is of a large diameter specification, and a width D (as shown in FIG. 2B) of each of the conductive vias 220 is greater than 11 micrometers (μm). End surfaces of the conductive vias 220 have contacts 223 on one side of the intermediate component 22 to be bonded and electrically connected to a plurality of conductors 222. The conductors 222 are covered with a protective film 221 made of such as a passivation material. For example, the conductors 222 are conductive lines, spherical conductive elements such as solder balls, pillar-shaped conductive elements such as copper pillars or solder bumps, or stud-shaped conductive elements made by a wire bonding machine, but the present disclosure is not limited to as such.

Furthermore, a protective layer 28b embedded in the first surface 25a of the encapsulation layer 25 is disposed on the other side of the intermediate component 22. For example, the protective layer 28b is in the form of a die attach film (DAF), covers the other end surfaces of the conductive vias 220, and is exposed from the first surface 25a of the encapsulation layer 25.

It should be understood that the conductive vias 220 can be in various forms. For instance, the outer periphery of each of the conductive vias 220 can be covered with an insulating material, and there is no special limitation.

A plurality of the conductive pillars 23 are embedded in the encapsulation layer 25, and the conductive pillars 23 are made of a metal material such as copper or a solder material.

In one embodiment, one end surface of each of the conductive pillars 23 is exposed from the first surface 25a of the encapsulation layer 25.

The circuit structure 20 is disposed on the second surface 25b of the encapsulation layer 25 and is electrically connected to the conductive pillars 23 and the conductors 212, 222.

In one embodiment, the circuit structure 20 includes a plurality of dielectric layers 200 and a plurality of circuit layers 201 formed on the dielectric layers 200, such as of a redistribution layer (RDL) specification. The outermost dielectric layer 200 can be used as a solder-resist layer, and the outermost circuit layer 201 is exposed from the solder-resist layer to serve as electrical contact pads. Alternatively, the circuit structure 20 may also include only a single dielectric layer 200 and a single circuit layer 201.

In addition, the circuit layer 201 is made of copper. The dielectric layer 200 is made of a dielectric material such as polybenzoxazole (PBO), polyimide (PI), prepreg (PP), or the like, or the dielectric layer 200 is made of a solder-resist material such as solder mask, ink, or the like.

The functional component 26 is disposed on the outermost layer of the circuit structure 20 and is electrically connected to the circuit layer 201. Accordingly, the encapsulation layer 25, the conductive pillars 23, the electronic component 21 and the intermediate component 22 are disposed on one side of the circuit structure 20, and the functional component 26 is disposed on the other side of the circuit structure 20. The functional component 26 is an active component, a passive component, or a combination of the active component and the passive component. The active component is, for example, a semiconductor chip. The passive component is, for example, a resistor, a capacitor, or an inductor.

In one embodiment, the functional component 26 is a semiconductor chip. The functional component 26 is electrically connected to the circuit layer 201 via a plurality of conductive bumps 260 in a flip-chip manner, and then the conductive bumps 260 are covered with an underfill 261; alternatively, the functional component 26 may also be electrically connected to the circuit layer 201 via a plurality of bonding wires (not shown) in a wire-bonding manner; or, the functional component 26 may be directly in contact with the circuit layer 201. If the functional component 26 is a passive component, the functional component 26 can be electrically connected to the circuit layer 201 via the conductive bumps 260. It should be understood that there is no particular limitation on the way the functional component 26 is electrically connected to the circuit layer 201.

Moreover, a plurality of the functional components 26 are disposed on the circuit structure 20. The electronic component 21 and/or the intermediate component 22 may be used as bridge components (bridge dies), so that the electronic component 21 and/or the intermediate component 22 are electrically connected to the circuit layer 201 of the circuit structure 20 via the conductors 212, 222, so as to electrically bridge the plurality of functional components 26.

Furthermore, a packaging layer 27 may be formed on the outermost layer of the circuit structure 20 to encapsulate the functional components 26 and the underfill 261, and there is no need to form the underfill 261 if the packaging layer 27 is used to encapsulate the conductive bumps 260. For example, the packaging layer 27 is made of polyimide (PI), dry film, epoxy molding colloid, epoxy molding compound, or other insulating materials, and the packaging layer 27 can be formed by lamination or molding. It should be understood that the encapsulation layer 25 and the packaging layer 27 can be made by the same or different materials.

In addition, the packaging layer 27 can encapsulate top surfaces of the functional components 26. Alternatively, as required, an outer surface of the packaging layer 27 may be flush with the top surfaces of the functional components 26, so that the top surfaces of the functional components 26 are exposed from the packaging layer 27.

As shown in FIG. 2B, a leveling process is performed on the first surface 25a of the encapsulation layer 25. The protective layer 28b on the intermediate component 22 is removed, and the protective layer 28 on the electronic component 21 is retained, so that the conductive vias 220 are exposed from the intermediate component 22. The intermediate component 22 and the conductive vias 220 are exposed from the first surface 25a of the encapsulation layer 25. The thickness of the protective layer 28a is different from the thickness of the protective layer 28b (that is, the thickness of the electronic component 21 is different from the thickness of the intermediate component 22). The thickness of the protective layer 28a on the electronic component 21 is greater than the thickness of the protective layer 28b on the intermediate component 22.

In one embodiment, a leveling process is performed to remove the protective layer 28b on the intermediate component 22, a portion of the first surface 25a of the encapsulation layer 25, a portion of each of the conductive pillars 23, and a portion of the protective layer 28a of the electronic component 21, so that the outer surface of the intermediate component 22, the end surfaces of the conductive vias 220, the first surface 25a of the encapsulation layer 25, the end surfaces of the conductive pillars 23, and the outer surface of the protective layer 28 on the electronic component 21 are flush with each other. For example, a grinding method is used in the leveling process to thin the protective layer 28 on the electronic component 21.

It should be understood that a variety of removal methods can be used in the leveling process, not limited to grinding.

As shown in FIG. 2C, a plurality of conductive components 29 are formed on the first surface 25a of the encapsulation layer 25 and are electrically connected to the conductive pillars 23 and the conductive vias 220.

In one embodiment, each of the conductive components 29 is a solder ball or a metal bump such as a copper bump. For example, the conductive components 29 are solder balls of type C4 (controlled collapse chip connection), so that the electronic package 2 is connected to an electronic device such as a circuit board (not shown) via the conductive components 29.

Moreover, an insulating protective layer 24 having a plurality of openings 240 may be formed on the first surface 25a of the encapsulation layer 25, and the openings 240 expose the protective layer 28, the conductive pillars 23, and the conductive vias 220. A plurality of conductive blind vias 241 are formed in the openings 240 and bonded to the plurality of conductive components 29.

Therefore, in the manufacturing method of this embodiment, a protective layer 28a embedded in the first surface 25a of the encapsulation layer 25 is disposed on the inactive surface 21b of the electronic component 21, and a protective layer 28b embedded in the first surface 25a of the encapsulation layer 25 is also disposed on the intermediate component 22. As a result, during the leveling process of the first surface 25a of the encapsulation layer 25, the differences in the materials to be removed (for example, the insulating material [the encapsulation layer 25, the protective layer 28a, and the protective layer 28b] and the copper material [the conductive pillars 23]) are smaller, and thus easier to grind. Therefore, compared with the prior art, the method of this embodiment can effectively avoid the problem of uneven grinding surface to form a flat grinding surface (for example, the outer surface of the intermediate component 22, the end surfaces of the conductive vias 220, the first surface 25a of the encapsulation layer 25, the end surfaces of the conductive pillars 23, and the outer surface of the protective layer 28 on the electronic component 21 are flush with each other). This is beneficial for the subsequent alignment and bonding of the conductive components 29, thereby improving the reliability and yield of the electronic package 2.

Furthermore, the protective layer 28 is disposed on the inactive surface 21b of the electronic component 21, so that the conventional copper migration problem does not occur. Therefore, compared with the prior art, the manufacturing method of this embodiment can effectively avoid the problem of electrical short circuit to ensure that the electrical function of the electronic component 21 is normal, thereby improving the reliability and yield of the electronic package 2.

In addition, the protective layer 28 can effectively enhance the bonding between the electronic component 21 and the insulating protective layer 24. Therefore, compared with the prior art, the manufacturing method of this embodiment can effectively avoid the delamination problem to ensure normal electrical conduction between the conductive components 29 and the conductive vias 220 (or the conductive pillars 23), thereby improving the reliability and yield of the electronic package 2.

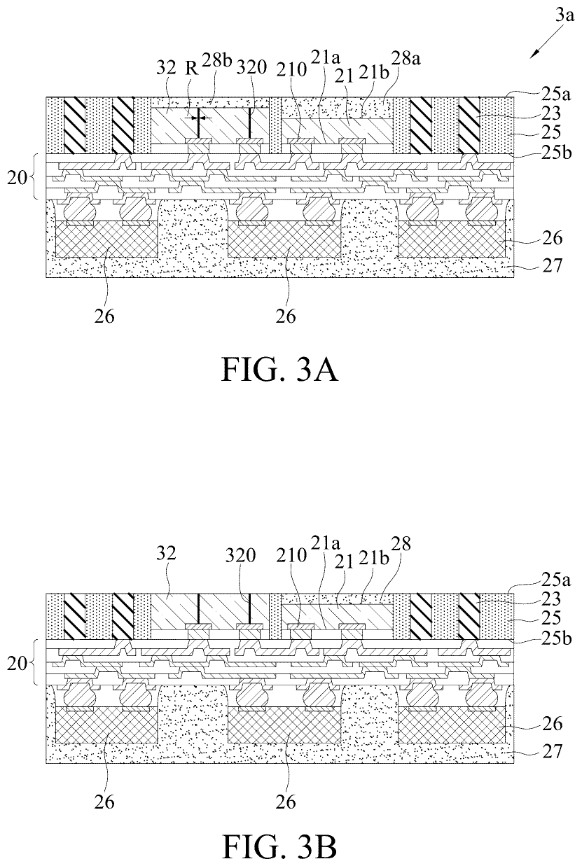

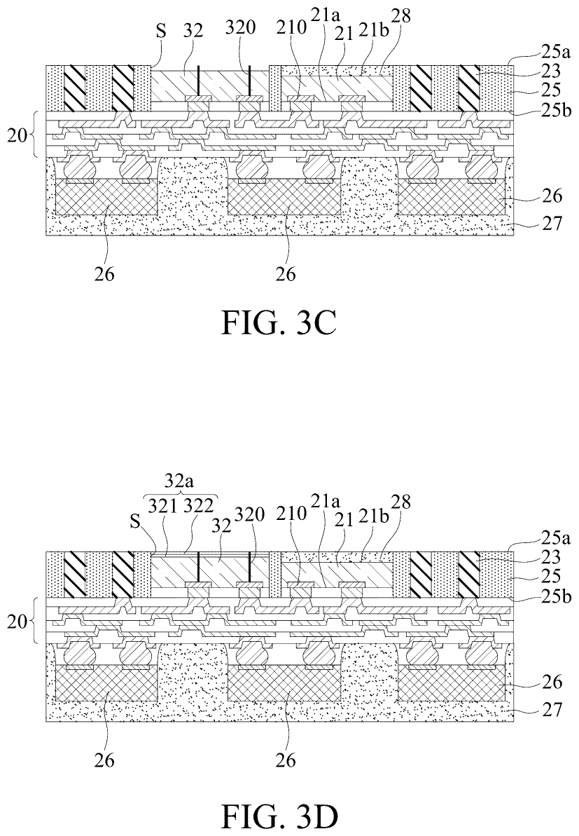

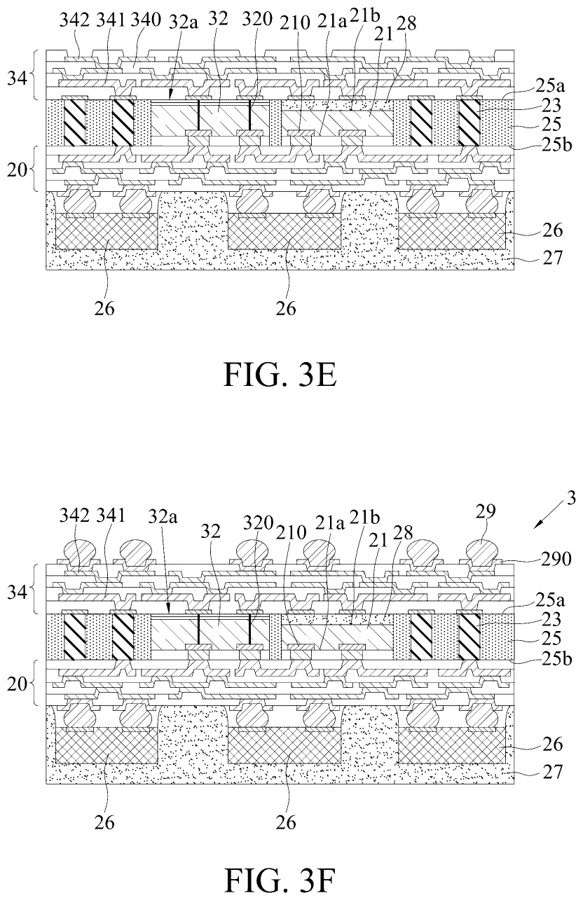

FIG. 3A to FIG. 3F are schematic cross-sectional views illustrating a method of manufacturing an electronic package 3 according to a second embodiment of the present disclosure. The difference between the second embodiment and the first embodiment lies in the specification of an intermediate component 32, so the similarities will not be described in detail below.

As shown in FIG. 3A, an electronic module 3a is provided substantially the same as that shown in FIG. 2A, with the main difference being that each of conductive vias 320 of the intermediate component 32 is of a small diameter specification with a width R of less than 11 micrometers (μm).

As shown in FIG. 3B, the leveling process shown in FIG. 2B is performed to remove the protective layer 28b on the intermediate component 32, so that the conductive vias 320 are exposed from the intermediate component 32, and the intermediate component 32 is exposed from the first surface 25a of the encapsulation layer 25. The surface of the intermediate component 32, the first surface 25a of the encapsulation layer 25, the end surfaces of the conductive pillars 23, and the outer surface of the protective layer 28 of the electronic component 21 are flush with each other.

As shown in FIG. 3C, a recess S is formed on the intermediate component 32, so that ends of the conductive vias 320 protrude out of a bottom surface of the recess S.

In one embodiment, the recess S is formed by etching silicon material, but the method of forming the recess S is not limited to the above.

As shown in FIG. 3D, a passivation structure 32a is formed in the recess S to cover the ends of the conductive vias 320, and the end surfaces of the conductive vias 320 are exposed from the passivation structure 32a.

In one embodiment, the passivation structure 32a includes at least one or more passivation layers 321, 322. For example, the passivation layers 321 and 322 are oxide layers or nitride layers, made of such as silicon nitride (SiN) and/or silicon oxide (SiO₂), but the present disclosure is not limited to as such.

Moreover, the process of forming the passivation structure 32a may first form at least one passivation layer 321, 322 on the first surface 25a of the encapsulation layer 25, the end surfaces of the conductive pillars 23, the protective layer 28, and the wall surfaces and bottom surface of the recess S, then remove the passivation layers 321, 322 on the first surface 25a of the encapsulation layer 25, the end surfaces of the conductive pillars 23, the protective layer 28, and the wall surfaces of the recess S, and retain only the passivation layers 321, 322 on the bottom surface of the recess S. For example, by means of a leveling process, a portion of the first surface 25a of the encapsulation layer 25 and the passivation layers 321, 322 thereon, a portion of each of the conductive pillars 23 and the passivation layers 321, 322 thereon, and a portion of the protective layer 28 and the passivation layers 321, 322 thereon are removed by grinding, so that the surface of the passivation structure 32a, the first surface 25a of the encapsulation layer 25, the end surfaces of the conductive pillars 23, and the outer surface of the protective layer 28 on the electronic component 21 are flush with each other. Accordingly, the passivation structure 32a and the end surfaces of the conductive vias 320 are exposed from the first surface 25a of the encapsulation layer 25.

It should be understood that there are many processes for forming the passivation structure 32a, and the present disclosure is not limited to the above.

As shown in FIG. 3E, a routing structure 34 (e.g., a wiring structure) is formed on the first surface 25a of the encapsulation layer 25, so that the routing structure 34 is electrically connected to the conductive pillars 23 and the conductive vias 320 of the intermediate component 32.

In one embodiment, the routing structure 34 includes a plurality of insulating layers 340 and a plurality of routing layers 341 (e.g., wiring layers), such as of a redistribution layer (RDL) specification, formed on the insulating layers 340 and electrically connected to the conductive pillars 23 and the conductive vias 320. The outermost insulating layer 340 can be used as a solder-resist layer. The outermost routing layer 341 is exposed from the solder-resist layer to serve as electrical contact pads 342. Alternatively, the routing structure 34 may also include only a single insulating layer 340 and a single routing layer 341.

Furthermore, the routing layer 341 is made of copper. The insulating layer 340 is made of a dielectric material such as polybenzoxazole (PBO), polyimide (PI), prepreg (PP), or the like, or the insulating layer 340 is made of a solder-resist material such as solder mask, ink, or the like.

As shown in FIG. 3F, a plurality of conductive components 29 are formed on the electrical contact pads 342 and electrically connected to the routing layer 341, so that the electronic package 3 is connected to an electronic device such as a circuit board (not shown) via the conductive components 29.

In one embodiment, the conductive components 29 are solder balls of type C4 (controlled collapse chip connection), and an under bump metallization (UBM) layer 290 for bonding to the conductive components 29 may be formed on the electrical contact pads 342.

Therefore, in the manufacturing method of this embodiment, a protective layer 28a embedded in the first surface 25a of the encapsulation layer 25 is disposed on the inactive surface 21b of the electronic component 21, and a protective layer 28b embedded in the first surface 25a of the encapsulation layer 25 is also disposed on the intermediate component 32. As a result, during the leveling process of the first surface 25a of the encapsulation layer 25, the differences in the materials to be removed (for example, the insulating material [the encapsulation layer 25, the protective layer 28a, and the protective layer 28b] and the copper material [the conductive pillars 23]) are smaller, and thus easier to grind. Therefore, compared with the prior art, the method of this embodiment can effectively avoid the problem of uneven grinding surface to form a flat grinding surface (for example, the outer surface of the intermediate component 32, the end surfaces of the conductive vias 320, the first surface 25a of the encapsulation layer 25, the end surfaces of the conductive pillars 23, and the outer surface of the protective layer 28 on the electronic component 21 are flush with each other, as shown in FIG. 3B). This is beneficial for the subsequent alignment and bonding of the routing structure 34 and the conductive components 29, thereby improving the reliability and yield of the electronic package 3.

In addition, the protective layer 28 is disposed on the inactive surface 21b of the electronic component 21, so that the conventional copper migration problem does not occur. Therefore, compared with the prior art, the manufacturing method of this embodiment can effectively avoid the problem of electrical short circuit to ensure that the electrical function of the electronic component 21 is normal, thereby improving the reliability and yield of the electronic package 3.

Moreover, the protective layer 28 can enhance the bonding between the electronic component 21 and the insulating layer 340 of the routing structure 34. Therefore, compared with the prior art, the manufacturing method of this embodiment can effectively avoid the delamination problem to ensure normal electrical conduction between the routing layer 341 of the routing structure 34 and the conductive vias 320 (or the conductive pillars 23), thereby improving the reliability and yield of the electronic package 3.

The present disclosure further provides an electronic package 2, 3, which comprises: an encapsulation layer 25, at least one electronic component 21 embedded in the encapsulation layer 25, at least one intermediate component 22, 32 embedded in the encapsulation layer 25, and a protective layer 28 embedded in the encapsulation layer 25.

The encapsulation layer 25 has a first surface 25a and a second surface 25b opposite to the first surface 25a.

The electronic component 21 is used as a bridge die and has an active surface 21a and an inactive surface 21b opposite to the active surface 21a, wherein the active surface 21a of the electronic component 21 faces the second surface 25b of the encapsulation layer 25 and has a plurality of electrode pads 210.

The intermediate component 22, 32 is used as a bridge die and has a plurality of conductive vias 220, 320 penetrating through the intermediate component 22, 32.

The protective layer 28 is embedded in the first surface 25a of the encapsulation layer 25 and bonded to the inactive surface 21b of the electronic component 21 but is not disposed on the intermediate component 22, 32.

In one embodiment, an insulating protective layer 24 having a plurality of openings 240 is formed on the protective layer 28 and the first surface 25a of the encapsulation layer 25, and a plurality of conductive blind vias 241 are formed in the plurality of openings 240 and connected to a plurality of conductive components 29.

In one embodiment, an insulating protective layer 24 having a plurality of openings 240 is formed on the intermediate component 22 and the first surface 25a of the encapsulation layer 25, wherein the plurality of openings 240 correspond to the conductive vias 220, wherein the conductive blind vias 241 are formed in the openings 240 and electrically connected to the conductive vias 220, and the conductive blind vias 241 are connected to the conductive components 29.

In one embodiment, a routing structure 34 is formed on the protective layer 28 and the first surface 25a of the encapsulation layer 25.

In one embodiment, a routing structure 34 is formed on the intermediate component 32 and the first surface 25a of the encapsulation layer 25 and is electrically connected to the conductive vias 320.

In one embodiment, a width D of each of the conductive vias 220 is greater than 11 microns.

In one embodiment, a width R of each of the conductive vias 320 is less than 11 microns.

In one embodiment, a circuit structure 20 is disposed on the second surface 25b of the encapsulation layer 25 and the active surface 21a of the electronic component 21 and is electrically connected to the electrode pads 210. For example, a plurality of functional components 26 are disposed on the circuit structure 20, and the electronic component 21 and/or the intermediate component 22, 32 electrically bridge the plurality of functional components 26 via the circuit structure 20.

In one embodiment, a passivation structure 32a is formed on the intermediate component 32 and covers ends of the conductive vias 320, and end surfaces of the conductive vias 320 are exposed from the passivation structure 32a.

To sum up, in the electronic package and the manufacturing method thereof according to the present disclosure, a protective layer embedded in the first surface of the encapsulation layer is disposed on both the inactive surface of the electronic component and the intermediate component (the thickness of the electronic component is different from the thickness of the intermediate component). Therefore, the differences in the materials to be removed are smaller when the leveling process is performed on the first surface of the encapsulation layer. Accordingly, the present disclosure can effectively avoid the problem of uneven grinding surface to form a flat grinding surface. This is beneficial to the subsequent alignment and bonding of the conductive components, thereby improving the reliability and yield of the electronic package.

Furthermore, the protective layer is disposed on the inactive surface of the electronic component, so that the conventional copper migration problem does not occur. Therefore, the present disclosure can effectively avoid the problem of electrical short circuit to ensure that the electrical function of the electronic component is normal, thereby improving the reliability and yield of the electronic package.

In addition, the protective layer can enhance the bonding between the electronic component and the insulating protective layer. Therefore, the present disclosure can effectively avoid the delamination problem to ensure normal electrical conduction between the conductive components and the conductive vias, thereby improving the reliability and yield of the electronic package.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
an encapsulation layer having a first surface and a second surface opposite to the first surface;
an electronic component embedded in the encapsulation layer to serve as a bridge die and having an active surface and an inactive surface opposite to the active surface, wherein the active surface of the electronic component faces the second surface of the encapsulation layer;
an intermediate component embedded in the encapsulation layer to serve as a bridge die and having a plurality of conductive vias; and
a protective layer embedded in the first surface of the encapsulation layer and bonded to the inactive surface of the electronic component, wherein the protective layer is free from being formed on the intermediate component.

2. The electronic package of claim 1, further comprising: an insulating protective layer formed on the protective layer and the first surface of the encapsulation layer and having a plurality of openings; and a plurality of conductive blind vias formed in the plurality of openings and connected to a plurality of conductive components.

3. The electronic package of claim 1, further comprising: an insulating protective layer formed on the intermediate component and the first surface of the encapsulation layer and having a plurality of openings, wherein the plurality of openings correspond to the plurality of conductive vias; and a plurality of conductive blind vias formed in the plurality of openings, electrically connected to the plurality of conductive vias, and connected to a plurality of conductive components.

4. The electronic package of claim 1, further comprising: a routing structure formed on the protective layer and the first surface of the encapsulation layer.

5. The electronic package of claim 1, further comprising: a routing structure formed on the intermediate component and the first surface of the encapsulation layer and electrically connected to the plurality of conductive vias.

6. The electronic package of claim 1, wherein a width of each of the plurality of conductive vias is greater than 11 microns.

7. The electronic package of claim 1, wherein a width of each of the plurality of conductive vias is less than 11 microns.

8. The electronic package of claim 1, further comprising: a circuit structure disposed on the second surface of the encapsulation layer and the active surface of the electronic component and electrically connected to the electronic component.

9. The electronic package of claim 8, further comprising: a plurality of functional components disposed on the circuit structure, wherein the electronic component and/or the intermediate component electrically bridge the plurality of functional components via the circuit structure.

10. The electronic package of claim 1, further comprising: a passivation structure formed on the intermediate component and covering ends of the plurality of conductive vias, wherein end surfaces of the plurality of conductive vias are exposed from the passivation structure.

11. A method of manufacturing an electronic package, comprising:
providing an electronic module, the electronic module comprising: an encapsulation layer having a first surface and a second surface opposite to the first surface, an electronic component embedded in the encapsulation layer to serve as a bridge die, and an intermediate component embedded in the encapsulation layer to serve as a bridge die, wherein the electronic component has an active surface and an inactive surface opposite to the active surface, and the active surface of the electronic component faces the second surface of the encapsulation layer, wherein the intermediate component has a plurality of conductive vias, and a protective layer embedded in the first surface of the encapsulation layer is disposed on the inactive surface of the electronic component and the intermediate component; and
performing a leveling process on the first surface of the encapsulation layer to remove the protective layer on the intermediate component, wherein the protective layer on the electronic component is retained.

12. The method of claim 11, further comprising: forming an insulating protective layer having a plurality of openings on the protective layer on the electronic component and the first surface of the encapsulation layer; and forming a plurality of conductive blind vias in the plurality of openings to connect to a plurality of conductive components.

13. The method of claim 11, further comprising: forming an insulating protective layer having a plurality of openings on the intermediate component and the first surface of the encapsulation layer, wherein the plurality of openings correspond to the plurality of conductive vias; and forming a plurality of conductive blind vias in the plurality of openings, wherein the plurality of conductive blind vias are electrically connected to the plurality of conductive vias and connected to a plurality of conductive components.

14. The method of claim 11, further comprising: forming a routing structure on the protective layer on the electronic component and the first surface of the encapsulation layer.

15. The method of claim 11, further comprising: forming a routing structure on the intermediate component and the first surface of the encapsulation layer, wherein the routing structure is electrically connected to the plurality of conductive vias.

16. The method of claim 11, wherein a width of each of the plurality of conductive vias is greater than 11 microns.

17. The method of claim 11, wherein a width of each of the plurality of conductive vias is less than 11 microns.

18. The method of claim 11, wherein a circuit structure is disposed on the second surface of the encapsulation layer and the active surface of the electronic component and is electrically connected to the electronic component.

19. The method of claim 18, wherein a plurality of functional components are disposed on the circuit structure, and the electronic component and/or the intermediate component electrically bridge the plurality of functional components via the circuit structure.

20. The method of claim 11, further comprising: forming a passivation structure covering ends of the plurality of conductive vias on the intermediate component, wherein end surfaces of the plurality of conductive vias are exposed from the passivation structure.
